(19) United States
(12) Patent Application Publication
(10) Pub. No.: US 2026/0324519 A1
(43) Pub. Date: Oct. 15, 2026

(54) SEMICONDUCTOR DEVICE

(71) Applicant: FUJI ELECTRIC CO., LTD., Kawasaki-shi (JP)

(72) Inventors: Akira HIRAO, Matsumoto-city (JP); Koji OSAKI, Matsumoto-city (JP); Taisuke FUKUDA, Matsumoto-city (JP)

(73) Assignee: FUJI ELECTRIC CO., LTD., Kawasaki-shi (JP)

(21) Appl. No.: 19/688,153

(22) Filed: May 26, 2026

Related U.S. Application Data
(63) Continuation of application No. PCT/JP2025/016779, filed on May 7, 2025.

(30) Foreign Application Priority Data
Jun. 7, 2024 (JP) 2024-093196

(51) Int. Cl. H10W 90/00; H10W 70/65; H10W 90/10

(52) U.S. Cl. CPC H10W 90/401; H10W 70/65; H10W 90/10; H10W 90/701

(57) ABSTRACT

A semiconductor device, including: an insulating circuit board including a conductive circuit pattern member; first and second semiconductor chips formed on the insulating circuit board, and having first and second electrodes thereon, respectively; a wiring board having first and second wiring holes, respectively facing the first and second electrodes, and a third wiring hole; first and second wiring pins respectively inserted into the first and second wiring holes, lower ends of the first and second wiring pins being electrically connected to the first and second electrodes, respectively, via a bonding material; and a conductive wiring member including a spacer portion, and a connecting portion protruding upward from an upper end surface of the spacer portion. A lower end surface of the conductive wiring member is bonded to the conductive circuit pattern member in a region on the insulating circuit board between the first and second semiconductor chips.

### CROSS-REFERENCE TO RELATED APPLICATION(S)

This application is a continuation application of International Application PCT/JP2025/016779 filed on May 7, 2025, which designated the U.S., and claims priority to Japanese Patent Application No. 2024-093196, filed on Jun. 7, 2024, the entire contents of which are incorporated herein by reference.

### BACKGROUND OF THE INVENTION

### 1. Field of the Invention

The embodiment discussed herein relates to a semiconductor device.

### 2. Background of the Related Art

A semiconductor device includes, for example, various electronic components such as a semiconductor chip that performs a switching operation and a control circuit that controls the switching operation of the semiconductor chip.

There is also a semiconductor device including an insulating circuit board and a printed circuit board. For example, a semiconductor device has been proposed in which a printed circuit board is arranged to face an insulating circuit board with a spacer portion interposed on a front surface of the insulating circuit board, and a pressing portion is arranged on the spacer portion with the printed circuit board interposed, the pressing portion being located on a front surface of the printed circuit board (see, for example, International Publication Pamphlet No. WO 2022/244392).

In addition, a power semiconductor module including a housing that accommodates a semiconductor chip, and at least one control pin or guide pin protruding outward from an upper surface of the housing has been proposed (see, for example, Japanese Laid-open Patent Publication No. 2018-195714).

### SUMMARY OF THE INVENTION

According to an aspect of the present disclosure, there is provided a semiconductor device, including: an insulating circuit board including a conductive circuit pattern member, an upper surface of the conductive circuit pattern member being that of the insulating circuit board; a first semiconductor chip and a second semiconductor chip formed on the insulating circuit board, and having a first electrode and a second electrode on upper surfaces thereof, respectively; a wiring board having a lower surface facing the upper surface of the insulating circuit board, the wiring board having a first wiring hole, a second wiring hole, and a third wiring hole formed therein, the first wiring hole and the second wiring hole respectively facing the first electrode and the second electrode; a first wiring pin and a second wiring pin respectively inserted into the first wiring hole and the second wiring hole, lower ends of the first wiring pin and the second wiring pin being electrically connected to the first electrode and the second electrode, respectively, via a bonding material; and a conductive wiring member including: a spacer portion, including: an upper end surface bonded to the lower surface of the wiring board around the third wiring hole, and a lower end surface bonded to the upper surface of the conductive circuit pattern member, the spacer portion maintaining a predetermined interval between the lower surface of the wiring board and the upper surface of the conductive circuit pattern member; and a connecting portion protruding upward from the upper end surface of the spacer portion and inserted into the third wiring hole, wherein the lower end surface of the conductive wiring member is bonded to the conductive circuit pattern member in a region on the insulating circuit board between the first semiconductor chip and the second semiconductor chip.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 illustrates a perspective view depicting an appearance of a semiconductor device according to an embodiment;

FIG. 2 is a side view of a semiconductor module in a state in which a sealing member is removed;

FIG. 3 is a plan view of an insulating circuit board;

FIG. 4 is a plan view illustrating an example of conductive wiring pattern members formed in a wiring board;

FIG. 5 illustrates an example of a circuit configuration of an inverter circuit;

FIG. 6 is a perspective view illustrating shapes of wiring members;

FIG. 7 is an enlarged cross-sectional view of attachment regions of wiring pins and wiring members;

FIG. 8 illustrates a comparative example relating to bonding of a wiring pin;

FIG. 9 is a flowchart illustrating a manufacturing process of the semiconductor device;

FIG. 10 illustrates a modification example in which part of a conductive circuit pattern member of the insulating circuit board is modified; and

FIGS. 11A to 11C illustrate modification examples of shapes of the wiring members.

### DETAILED DESCRIPTION OF THE INVENTION

Hereinafter, an embodiment will be described with reference to the drawings. In the following description, “front surface” and “upper surface” represent an X-Y plane facing upward (+Z direction) in a semiconductor device illustrated in the drawings. Similarly, “upper” represents an upward (+Z direction) direction in the semiconductor device illustrated in the drawings. “Back surface” and “lower surface” represent an X-Y plane facing downward (−Z direction) in the semiconductor device illustrated in the drawings. Similarly, “lower” represents a downward (−Z direction) direction in the semiconductor device illustrated in the drawings. The same directional meanings apply to other drawings as needed. The expressions “front surface”, “upper surface”, “upper”, “back surface”, “lower surface”, “lower”, and “side surface” are merely convenient expressions for specifying relative positional relationships and do not limit the technical concept of the present disclosure. For example, “upper” and “lower” do not necessarily indicate vertical directions with respect to the ground. That is, the directions of “upper” and “lower” are not limited to a gravitational direction.

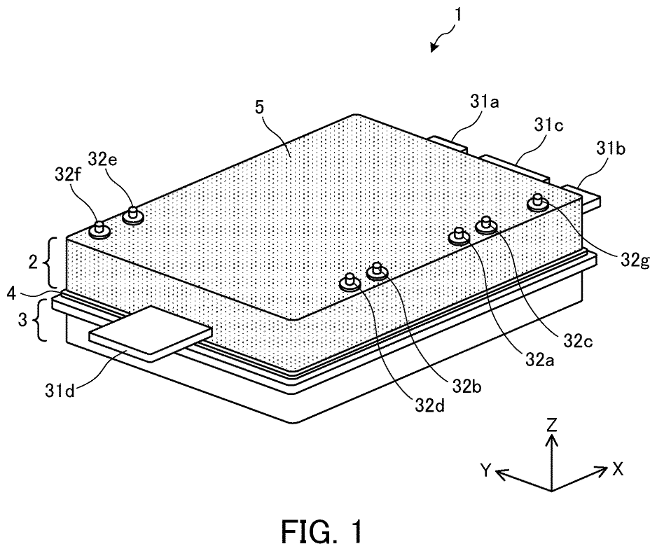

FIG. 1 illustrates a perspective view depicting an appearance of a semiconductor device according to the embodiment. A semiconductor device 1 includes a semiconductor module 2 and a cooler 3. The semiconductor module 2 and the cooler 3 are bonded by a bonding material 4.

The semiconductor module 2 includes a sealing member 5 that seals an insulating circuit board 10 and a wiring board 20 described later. The sealing member 5 is molded by a transfer method, and seals not only a region between the insulating circuit board 10 and the wiring board 20 facing each other, but also at least regions on side surfaces (±X-direction sides and ±Y-direction sides) of the insulating circuit board 10 and the wiring board 20, and a region on an upper-surface side of the wiring board 20. As a sealing material of the sealing member 5, a thermosetting resin is used. The thermosetting resin is, for example, an epoxy resin.

The semiconductor module 2 further includes plate-shaped external connection terminals 31a to 31d. Outer end portions of the external connection terminals 31a to 31c protrude from a side surface of the sealing member 5 on a +X-direction side and form connection terminal portions to be connected to an external circuit. Inner end portions of the external connection terminals 31a to 31c are connected to the insulating circuit board 10 inside the sealing member 5. An outer end portion of the external connection terminal 31d protrudes from a side surface of the sealing member 5 on a −X-direction side and forms a connection terminal portion to be connected to an external circuit. An inner end portion of the external connection terminal 31d is connected to the insulating circuit board 10 inside the sealing member 5. As described later, an inverter circuit is formed inside the semiconductor module 2. The external connection terminals 31a and 31b correspond to P terminals of the inverter circuit, the external connection terminal 31c corresponds to an N terminal of the inverter circuit, and the external connection terminal 31d corresponds to an O (Out) terminal that outputs the inverter circuit.

The semiconductor module 2 further includes external connection terminals 32a to 32g. The external connection terminals 32a to 32g form substantially columnar shapes extending in a vertical direction (±Z direction). Lower end portions (inner end portions) of the external connection terminals 32a to 32g are connected to the wiring board 20 inside the sealing member 5, and upper end portions (outer end portions) of the external connection terminals 32a to 32g protrude from an upper surface of the sealing member 5 and form connection terminal portions to be connected to an external circuit. The external connection terminals 32a and 32b correspond to gate control terminals of the inverter circuit, the external connection terminals 32c and 32d correspond to auxiliary source terminals of the inverter circuit, and the external connection terminals 32e to 32g correspond to sense signal terminals.

The cooler 3 includes, on an upper surface, a cooling surface on which the semiconductor module 2 is disposed. The bonding material 4 bonds a lower surface of the semiconductor module 2 (more specifically, a lower surface of a metal plate 12 described later) to the cooling surface of the cooler 3. Accordingly, the bonding material 4 fixes the semiconductor module 2 to the cooler 3 and thermally connects the metal plate 12 of the semiconductor module 2 to the cooler 3.

The bonding material 4 may be, for example, a brazing material or a thermal interface material. The brazing material includes, for example, at least one of a tin alloy, an aluminum alloy, a titanium alloy, a magnesium alloy, a zirconium alloy, and a silicon alloy as a main component. The thermal interface material includes, for example, an elastomer sheet, room temperature vulcanization (RTV) rubber, a gel, an adhesive including a phase change material or the like, or silicone mixed with ceramics.

Although not illustrated, a refrigerant circulates inside the cooler 3, and an inlet and an outlet for the refrigerant are provided on a side surface or a bottom surface of the cooler 3.

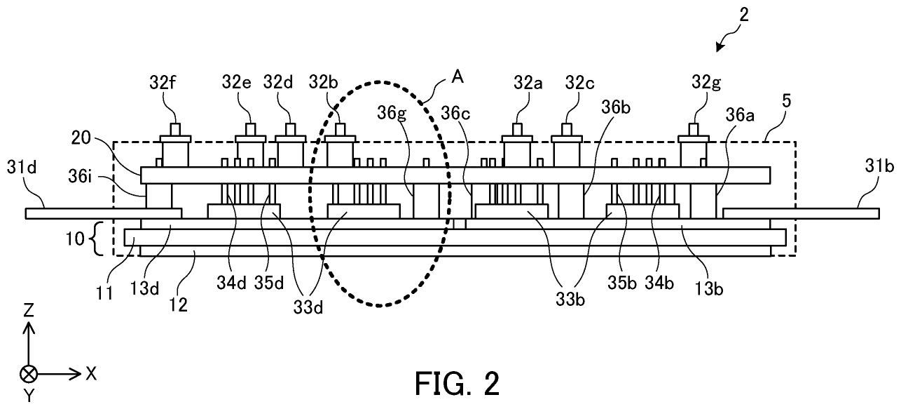

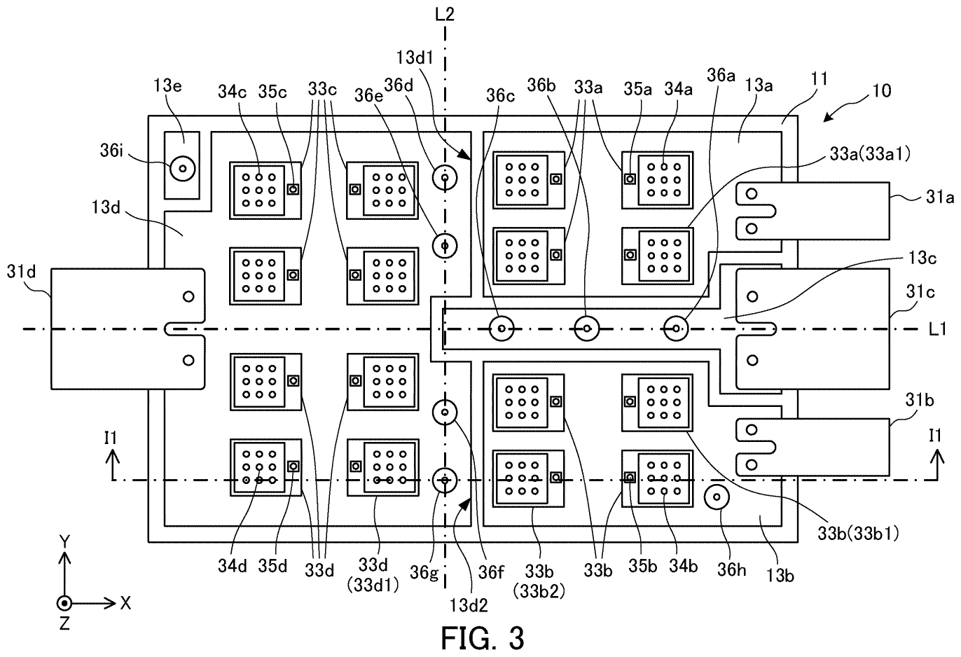

FIG. 2 is a side view of the semiconductor module in a state in which the sealing member is removed. FIG. 3 is a plan view of the insulating circuit board. FIG. 2 is a side view when the semiconductor module 2 is viewed in a −Y direction. FIG. 3 illustrates, for ease of explanation, a state in which wiring pins and wiring members are respectively bonded to semiconductor chips and conductive circuit pattern members on the insulating circuit board 10. In an actual process, the wiring pins and the wiring members are inserted into wiring holes formed in the wiring board 20, and thereafter lower ends of the wiring pins and the wiring members are respectively bonded to the semiconductor chips and the conductive circuit pattern members on the insulating circuit board 10.

The semiconductor module 2 includes the insulating circuit board 10 and the wiring board 20. The insulating circuit board 10 and the wiring board 20 each have a rectangular shape in plan view. The wiring board 20 is arranged with a lower surface facing an upper surface of the insulating circuit board 10, and is disposed with respect to the upper surface of the insulating circuit board 10 with a predetermined interval (interval D1 described later).

The insulating circuit board 10 includes an insulating plate 11, the metal plate 12 bonded to a lower surface of the insulating plate 11, and conductive circuit pattern members 13a to 13e formed on an upper surface of the insulating plate 11. The insulating plate 11 and the metal plate 12 each have a rectangular shape in plan view. Corner portions of the insulating plate 11 and the metal plate 12 may be R-chamfered or C-chamfered.

The insulating plate 11 is formed of a material having insulating properties and excellent thermal conductivity. The insulating plate 11 may be formed of ceramics or an insulating resin. The ceramics are, for example, aluminum oxide, aluminum nitride, or silicon nitride. The insulating resin is, for example, a paper phenol board, a paper epoxy board, a glass composite board, or a glass epoxy board.

The metal plate 12 is formed mainly of a metal having excellent thermal conductivity. The metal may be, for example, copper, aluminum, or an alloy including at least one of copper and aluminum. Plating treatment may be performed on a surface of the metal plate 12 in order to improve corrosion resistance. In this case, a plating material may include at least one of nickel and tin. A lower surface of the metal plate 12 also serves as a lower surface of the insulating circuit board 10 and is exposed from a lower surface of the sealing member 5. The lower surface of the metal plate 12 is bonded, via the bonding material 4, to the cooling surface on the upper surface of the cooler 3.

The conductive circuit pattern members 13a to 13e are formed of a metal having excellent electrical conductivity and containing copper. The metal is, for example, copper, aluminum, or an alloy mainly including at least one of copper and aluminum. The conductive circuit pattern members 13a to 13e are formed on the upper surface of the insulating plate 11 as follows. A metal plate is formed on the upper surface of the insulating plate 11, and the metal plate is subjected to etching or the like to obtain the conductive circuit pattern members 13a to 13e having predetermined shapes. Alternatively, the conductive circuit pattern members 13a to 13e cut in advance from a metal plate may be pressure-bonded to the upper surface of the insulating plate 11.

The conductive circuit pattern member 13a (the second conductive circuit pattern member) is electrically connected to the external connection terminal 31a. The external connection terminal 31a has a plate shape, and a lower surface of an end portion of the external connection terminal 31a on a −X-direction side is bonded to an upper surface of an end portion of the conductive circuit pattern member 13a on a +X-direction side. On the other hand, an end portion of the external connection terminal 31a on a +X-direction side protrudes from the sealing member 5 and forms a connection terminal portion to be connected to an external circuit.

The conductive circuit pattern member 13b (the third conductive circuit pattern member) is electrically connected to the external connection terminal 31b. The external connection terminal 31b has a plate shape, and a lower surface of an end portion of the external connection terminal 31b on a −X-direction side is bonded to an upper surface of an end portion of the conductive circuit pattern member 13b on a +X-direction side. On the other hand, an end portion of the external connection terminal 31b on a +X-direction side protrudes from the sealing member 5 and forms a connection terminal portion to be connected to an external circuit. In addition, the external connection terminal 31b has the same potential as the external connection terminal 31a. Accordingly, the conductive circuit pattern members 13a and 13b also have the same potential.

The conductive circuit pattern member 13c (the first conductive circuit pattern member) is electrically connected to the external connection terminal 31c. The external connection terminal 31c has a plate shape, and a lower surface of an end portion of the external connection terminal 31c on a −X-direction side is bonded to an upper surface of an end portion of the conductive circuit pattern member 13c on a +X-direction side. On the other hand, an end portion of the external connection terminal 31c on a +X-direction side protrudes from the sealing member 5 and forms a connection terminal portion to be connected to an external circuit.

The conductive circuit pattern member 13d (the fourth conductive circuit pattern member) is electrically connected to the external connection terminal 31d. The external connection terminal 31d has a plate shape, and a lower surface of an end portion of the external connection terminal 31d on a +X-direction side is bonded to an upper surface of an end portion of the conductive circuit pattern member 13d on a −X-direction side. On the other hand, an end portion of the external connection terminal 31d on a −X-direction side protrudes from the sealing member 5 and forms a connection terminal portion to be connected to an external circuit.

The external connection terminals 31a to 31d are formed of a metal having excellent electrical conductivity. The metal is, for example, copper, aluminum, or an alloy mainly including at least one of copper and aluminum. Plating treatment may be performed on surfaces of the external connection terminals 31a to 31d in order to improve corrosion resistance. In this case, a plating material may include at least one of nickel and tin.

Semiconductor chips 33a to 33d are mounted on the upper surface of the insulating circuit board 10. The semiconductor chips 33a to 33d may be power metal-oxide-semiconductor field-effect transistors (MOSFETs) mainly including silicon carbide. In the power MOSFET, a body diode functioning as a free wheeling diode (FWD) or a Schottky barrier diode (SBD) may be incorporated in one chip. Each of the semiconductor chips 33a to 33d includes, for example, an input electrode (a drain electrode) as a main electrode on a lower surface, and includes, on an upper surface, an output electrode (a source electrode) as a main electrode and a control electrode (a gate electrode).

In the present embodiment, a case in which the semiconductor chips 33a to 33d are power MOSFETs mainly including silicon carbide is described as above. However, as another example, the semiconductor chips 33a to 33d may include switching elements mainly including silicon. The switching elements are, for example, reverse-conducting insulated gate bipolar transistors (RC-IGBTs). An RC-IGBT is a semiconductor element in which an IGBT and an FWD are configured in one chip in an antiparallel manner. Each of the semiconductor chips 33a to 33d includes, for example, an input electrode (a collector electrode) as a main electrode on a lower surface, and includes, on an upper surface, an output electrode (an emitter electrode) as a main electrode and a control electrode (a gate electrode).

In addition, as another example, the semiconductor chips 33a to 33d may each be a semiconductor chip formed mainly of silicon and including a set of a switching element and a diode element. The switching element is, for example, a power MOSFET or an IGBT. The semiconductor chip including the switching element includes, for example, an input electrode as a main electrode on a lower surface (a drain electrode for the power MOSFET, and a collector electrode for the IGBT), and includes, on an upper surface, a gate electrode as a control electrode and an output electrode as a main electrode (a source electrode for the power MOSFET, and an emitter electrode for the IGBT). In addition, the diode element is, for example, an SBD or a P-intrinsic-N (PiN) diode used as an FWD. The semiconductor chip including the diode element includes, for example, an output electrode (a cathode electrode) as a main electrode on a lower surface and an input electrode (an anode electrode) as a main electrode on an upper surface.

In a case in which each of the semiconductor chips 33a to 33d is a set of a switching element and a diode element, conductive wiring pattern members of the wiring board 20 and conductive circuit pattern members of the insulating circuit board 10, each to be described later, are patterned such that an inverter circuit including the switching elements and the diode elements is formed.

The semiconductor chips 33a are mounted on the upper surface of the conductive circuit pattern member 13a. Although not illustrated, the input electrodes on the lower surfaces of the semiconductor chips 33a are electrically connected, via solder, to the upper surface of the conductive circuit pattern member 13a. Accordingly, the input electrodes on the lower surfaces of the semiconductor chips 33a and the external connection terminal 31a are electrically connected via the conductive circuit pattern member 13a.

The semiconductor chips 33b are mounted on the upper surface of the conductive circuit pattern member 13b. Although not illustrated, the input electrodes on the lower surfaces of the semiconductor chips 33b are electrically connected, via solder, to the upper surface of the conductive circuit pattern member 13b. Accordingly, the input electrodes on the lower surfaces of the semiconductor chips 33b and the external connection terminal 31b are electrically connected via the conductive circuit pattern member 13b.

The semiconductor chips 33c and 33d are mounted on the upper surface of the conductive circuit pattern member 13d. Although not illustrated, the input electrodes on the lower surfaces of the semiconductor chips 33c and 33d are electrically connected, via solder, to the upper surface of the conductive circuit pattern member 13d. Accordingly, the input electrodes on the lower surfaces of the semiconductor chips 33c and 33d and the external connection terminal 31d are electrically connected via the conductive circuit pattern member 13d.

In the present embodiment, four semiconductor chips are provided for each of the semiconductor chips 33a to 33d on the insulating circuit board 10. An inverter circuit is configured by a combination of one semiconductor chip from each of the semiconductor chips 33a to 33d.

Next, a configuration for electrically connecting the conductive circuit pattern members 13a to 13e and the semiconductor chips 33a to 33d on the insulating circuit board 10 to conductive wiring pattern members formed in the wiring board 20 will be described.

Output electrodes formed on the upper surfaces of the semiconductor chips 33a to 33d are respectively electrically connected, via wiring pins 34a to 34d, to predetermined conductive wiring pattern members formed in the wiring board 20. In the present embodiment, as an example, nine wiring pins are arranged with respect to the output electrode on the upper surface of each of the semiconductor chips 33a to 33d. In addition, control electrodes formed on the upper surfaces of the semiconductor chips 33a to 33d are respectively electrically connected, via wiring pins 35a to 35d, to predetermined conductive wiring pattern members formed in the wiring board 20. The control electrodes may be provided at a center of one side of the upper surface of each of the semiconductor chips 33a to 33d.

The wiring pins 34a to 34d and 35a to 35d each have a cylindrical shape extending in a vertical direction (±Z direction) and are inserted into wiring holes (through-holes) formed in the wiring board 20. Upper ends of the wiring pins 34a to 34d and 35a to 35d protrude from an upper surface of the wiring board 20. Lower ends of the wiring pins 34a to 34d are electrically connected, via a bonding material, to the output electrodes on the upper surfaces of the semiconductor chips 33a to 33d, respectively, and lower ends of the wiring pins 35a to 35d are electrically connected, via a bonding material, to the control electrodes on the upper surfaces of the semiconductor chips 33a to 33d, respectively. The wiring pins 34a to 34d and 35a to 35d are illustrated as having cylindrical shapes; however, the wiring pins 34a to 34d and 35a to 35d are not limited to cylindrical shapes and may each have, for example, a prismatic shape, a polygonal prismatic shape, or a star-shaped polygonal prismatic shape.

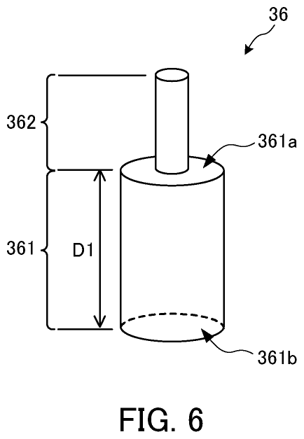

Wiring members 36a to 36i are arranged on the insulating circuit board 10. As described later in detail, the wiring members 36a to 36i are formed of the same conductive material as the wiring pins 34a to 34d and 35a to 35d, and include a cylindrical spacer portion 361 (see FIG. 6) and a connecting portion 362 (see FIG. 6) having a cylindrical shape thinner than the spacer portion 361 and protruding upward from the spacer portion 361. The connecting portions 362 of the wiring members 36a to 36i are inserted into wiring holes formed in the wiring board 20.

Lower end surfaces of the wiring members 36a to 36c are bonded to the upper surface of the conductive circuit pattern member 13c. Lower end surfaces of the wiring members 36d to 36g are bonded to the upper surface of the conductive circuit pattern member 13d. A lower end surface of the wiring member 36h is bonded to the upper surface of the conductive circuit pattern member 13b. A lower end surface of the wiring member 36i is bonded, using a bonding material, to the upper surface of the conductive circuit pattern member 13e.

The conductive circuit pattern member 13c is formed in a region sandwiched between the conductive circuit pattern members 13a and 13b and has a shape extending along a first center line L1 with respect to a ±Y direction in the insulating circuit board 10. The wiring members 36a to 36c are arranged along the first center line L1.

On the other hand, the wiring members 36d to 36g are arranged along a second center line L2 with respect to a ±X direction in the insulating circuit board 10. The wiring members 36d to 36g are arranged, along boundary lines 13d1 and 13d2, in edge regions of the conductive circuit pattern member 13d along the boundary lines 13d1 and 13d2, the boundary lines 13d1 and 13d2 facing the conductive circuit pattern members 13a and 13b, respectively. The second center line L2 does not necessarily have to be exactly centered with respect to the ±X direction in the insulating circuit board 10 and may be a line near a center.

The wiring pins 34a to 34d and 35a to 35d and the wiring members 36a to 36i are formed of a metal having excellent electrical conductivity. The metal is, for example, copper, aluminum, or an alloy mainly including at least one of copper and aluminum. Plating treatment may be performed on surfaces of the wiring pins 34a to 34d and 35a to 35d and the wiring members 36a to 36i in order to improve corrosion resistance. In this case, a plating material may include at least one of nickel and tin.

A bonding material used for bonding the wiring pins 34a to 34d and 35a to 35d to electrodes on the upper surfaces of the semiconductor chips, and for bonding the wiring members 36a to 36i to the conductive circuit pattern members is, for example, solder. Solder components constituting the solder include lead-free solder including a predetermined alloy as a main component. The predetermined alloy includes tin. The predetermined alloy is, for example, at least one alloy selected from an alloy of tin-silver, an alloy of tin-silver-copper, an alloy of tin-zinc-bismuth, an alloy of tin-copper, an alloy of tin-silver-indium-bismuth, and an alloy of tin-antimony. In addition, additives may be included in the solder components. The additives include, for example, nickel, germanium, cobalt, or silicon. Accordingly, the solder components include, for example, at least one of silver, zinc, copper, bismuth, indium, and antimony together with tin.

In addition, a sintered body may be used for the bonding in the above-described portions. In a case in which bonding is performed by the sintered body, a sintering material is, for example, powder including at least one of silver, iron, copper, aluminum, titanium, nickel, tungsten, and molybdenum.

Next, the wiring board 20 will be described. The wiring board 20 is, for example, a printed circuit board (PCB) having a multilayer structure. In the wiring board 20, wiring layers may be formed on at least one of an upper surface and a lower surface of an insulating layer, and a plurality of insulating layers may be laminated, and a wiring layer may also be formed on one of adjacent insulating layers.

The insulating layers are formed of, for example, an insulating resin. The insulating resin is, for example, a paper phenol board, a paper epoxy board, a glass composite board, a glass epoxy board, a Teflon (registered trademark) board, or a polyimide board. The wiring layers are formed of a metal having excellent electrical conductivity. The metal is, for example, copper, aluminum, or an alloy mainly including at least one of copper and aluminum.

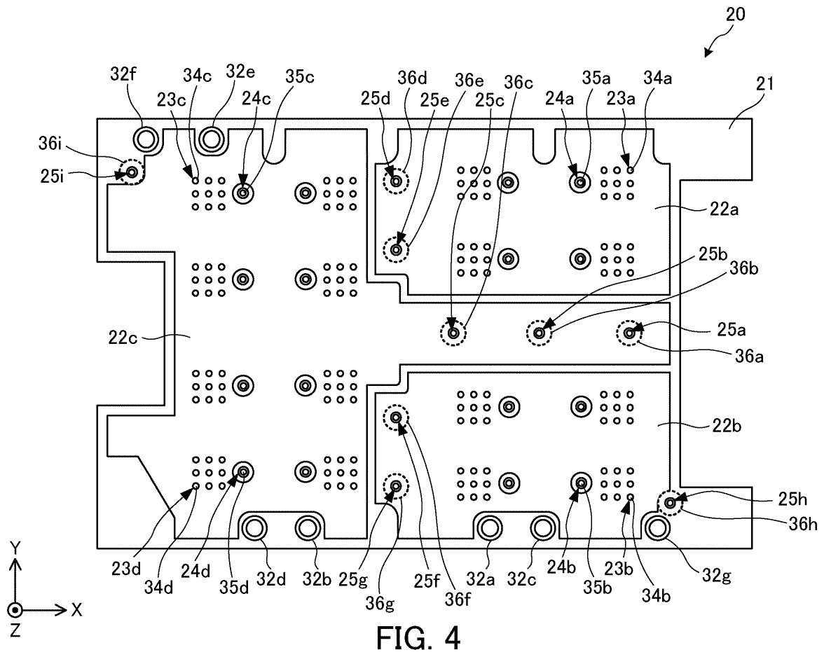

FIG. 4 is a plan view illustrating an example of conductive wiring pattern members formed in the wiring board. Here, as an example, the wiring board 20 includes, in order from an upper side (+Z-direction side), an upper insulating layer (not illustrated), an intermediate insulating layer 21, and a lower insulating layer (not illustrated). A first wiring layer is formed on an upper surface of the upper insulating layer, a second wiring layer is formed on an upper surface of the intermediate insulating layer 21, a third wiring layer is formed on a lower surface of the intermediate insulating layer 21, and a fourth wiring layer is formed on a lower surface of the lower insulating layer. FIG. 4 illustrates, as an example, conductive wiring pattern members of the second wiring layer formed on the upper surface of the intermediate insulating layer 21.

Conductive wiring pattern members 22a to 22c are formed on the upper surface of the intermediate insulating layer 21. The conductive wiring pattern members 22a to 22c are formed of a metal having excellent electrical conductivity and containing copper. The metal is, for example, copper, aluminum, or an alloy mainly including at least one of copper and aluminum.

Wiring holes 23a to 23d and 24a to 24d penetrating in a vertical direction (±Z direction) are formed in the wiring board 20.

The wiring hole 23a is formed at a position facing an output electrode provided on an upper surface of the semiconductor chip 33a on the insulating circuit board 10. A wiring pin 34a is inserted into the wiring hole 23a, and a lower end of the wiring pin 34a is electrically connected, via a bonding material, to the output electrode of the semiconductor chip 33a. In addition, the wiring hole 24a is formed at a position facing a control electrode provided on the upper surface of the semiconductor chip 33a on the insulating circuit board 10. A wiring pin 35a is inserted into the wiring hole 24a, and a lower end of the wiring pin 35a is electrically connected, via a bonding material, to the control electrode of the semiconductor chip 33a.

The wiring hole 23a is electrically connected to the conductive wiring pattern member 22a of the intermediate insulating layer 21. Accordingly, the output electrode of the semiconductor chip 33a and the conductive wiring pattern member 22a are electrically connected. On the other hand, the wiring hole 24a is not electrically connected to any of the conductive wiring pattern members of the intermediate insulating layer 21. Although not illustrated, the wiring hole 24a is electrically connected to another wiring layer of the wiring board 20 (for example, the first wiring layer which is an uppermost layer), and is electrically connected, in the wiring layer, to the external connection terminal 32a.

The wiring hole 23b is formed at a position facing an output electrode provided on an upper surface of the semiconductor chip 33b on the insulating circuit board 10. A wiring pin 34b is inserted into the wiring hole 23b, and a lower end of the wiring pin 34b is electrically connected, via a bonding material, to the output electrode of the semiconductor chip 33b. In addition, the wiring hole 24b is formed at a position facing a control electrode provided on the upper surface of the semiconductor chip 33b on the insulating circuit board 10. A wiring pin 35b is inserted into the wiring hole 24b, and a lower end of the wiring pin 35b is electrically connected, via a bonding material, to the control electrode of the semiconductor chip 33b.

The wiring hole 23b is electrically connected to the conductive wiring pattern member 22b of the intermediate insulating layer 21. Accordingly, the output electrode of the semiconductor chip 33b and the conductive wiring pattern member 22b are electrically connected. On the other hand, the wiring hole 24b is not electrically connected to any of the conductive wiring pattern members of the intermediate insulating layer 21. Although not illustrated, the wiring hole 24b is electrically connected to another wiring layer of the wiring board 20 (for example, the first wiring layer which is an uppermost layer), and is electrically connected, in the wiring layer, to the external connection terminal 32a.

The wiring hole 23c is formed at a position facing an output electrode provided on an upper surface of the semiconductor chip 33c on the insulating circuit board 10. A wiring pin 34c is inserted into the wiring hole 23c, and a lower end of the wiring pin 34c is electrically connected, via a bonding material, to the output electrode of the semiconductor chip 33c. In addition, the wiring hole 24c is formed at a position facing a control electrode provided on the upper surface of the semiconductor chip 33c on the insulating circuit board 10. A wiring pin 35c is inserted into the wiring hole 24c, and a lower end of the wiring pin 35c is electrically connected, via a bonding material, to the control electrode of the semiconductor chip 33c.

The wiring hole 23c is electrically connected to the conductive wiring pattern member 22c of the intermediate insulating layer 21. Accordingly, the output electrode of the semiconductor chip 33c and the conductive wiring pattern member 22c are electrically connected. On the other hand, the wiring hole 24c is not electrically connected to any of the conductive wiring pattern members of the intermediate insulating layer 21. Although not illustrated, the wiring hole 24c is electrically connected to another wiring layer of the wiring board 20 (for example, the first wiring layer which is an uppermost layer), and is electrically connected, in the wiring layer, to the external connection terminal 32b.

The wiring hole 23d is formed at a position facing an output electrode provided on an upper surface of the semiconductor chip 33d on the insulating circuit board 10. A wiring pin 34d is inserted into the wiring hole 23d, and a lower end of the wiring pin 34d is electrically connected, via a bonding material, to the output electrode of the semiconductor chip 33d. In addition, the wiring hole 24d is formed at a position facing a control electrode provided on the upper surface of the semiconductor chip 33d on the insulating circuit board 10. A wiring pin 35d is inserted into the wiring hole 24d, and a lower end of the wiring pin 35d is electrically connected, via a bonding material, to the control electrode of the semiconductor chip 33d.

The wiring hole 23d is electrically connected to the conductive wiring pattern member 22c of the intermediate insulating layer 21. Accordingly, the output electrode of the semiconductor chip 33d and the conductive wiring pattern member 22c are electrically connected. On the other hand, the wiring hole 24d is not electrically connected to any of the conductive wiring pattern members of the intermediate insulating layer 21. Although not illustrated, the wiring hole 24d is electrically connected to another wiring layer of the wiring board 20 (for example, the first wiring layer which is an uppermost layer), and is electrically connected, in the wiring layer, to the external connection terminal 32b.

In addition, wiring holes 25a to 25i penetrating in the vertical direction (±Z direction) are formed in the wiring board 20.

The connecting portions 362 (see FIG. 6) in upper portions of the wiring members 36a to 36c are respectively inserted into the wiring holes 25a to 25c. The wiring holes 25a to 25c are electrically connected to the conductive wiring pattern member 22c of the intermediate insulating layer 21. Accordingly, the conductive wiring pattern member 22c is electrically connected, via the wiring holes 25a to 25c, to the conductive circuit pattern member 13c of the insulating circuit board 10 and the external connection terminal 31c.

The connecting portions 362 (see FIG. 6) in upper portions of the wiring members 36d and 36e are respectively inserted into the wiring holes 25d and 25e. The wiring holes 25d and 25e are electrically connected to the conductive wiring pattern member 22a of the intermediate insulating layer 21. Accordingly, the conductive wiring pattern member 22a is electrically connected, via the wiring holes 25d and 25e, to the conductive circuit pattern member 13d of the insulating circuit board 10 and the external connection terminal 31d. In addition, with such a configuration, the conductive wiring pattern member 22a of the intermediate insulating layer 21 functions to electrically connect output electrodes on upper surfaces of the semiconductor chips 33a arranged on the conductive circuit pattern member 13a of the insulating circuit board 10 to input electrodes on lower surfaces of the semiconductor chips 33c and 33d arranged on the conductive circuit pattern member 13d of the insulating circuit board 10.

The connecting portions 362 (see FIG. 6) in upper portions of the wiring members 36f and 36g are respectively inserted into the wiring holes 25f and 25g. The wiring holes 25f and 25g are electrically connected to the conductive wiring pattern member 22b of the intermediate insulating layer 21. Accordingly, the conductive wiring pattern member 22b is electrically connected, via the wiring holes 25f and 25g, to the conductive circuit pattern member 13d of the insulating circuit board 10 and the external connection terminal 31d. In addition, with such a configuration, the conductive wiring pattern member 22b of the intermediate insulating layer 21 functions to electrically connect output electrodes on upper surfaces of the semiconductor chips 33b arranged on the conductive circuit pattern member 13b of the insulating circuit board 10 to input electrodes on lower surfaces of the semiconductor chips 33c and 33d arranged on the conductive circuit pattern member 13d of the insulating circuit board 10.

The connecting portion 362 (see FIG. 6) in an upper portion of the wiring member 36h is inserted into the wiring hole 25h. The wiring hole 25h is not electrically connected to any of the conductive wiring pattern members of the intermediate insulating layer 21. Although not illustrated, the wiring hole 25h is electrically connected to another wiring layer of the wiring board 20 (for example, the fourth wiring layer which is a lowermost layer), and is electrically connected, in the wiring layer, to the external connection terminal 32g. Since a lower end of the wiring member 36h is bonded to the conductive circuit pattern member 13b of the insulating circuit board 10, the external connection terminal 32g is electrically connected, via the wiring hole 25h and the conductive circuit pattern member 13b, to an input electrode on a lower surface of one of the semiconductor chips 33b. Accordingly, the external connection terminal 32g functions as a sense terminal for sensing a voltage at the input electrode (the drain electrode).

The connecting portion 362 (see FIG. 6) in an upper portion of the wiring member 36i is inserted into the wiring hole 25i. The wiring hole 25i is not electrically connected to any of the conductive wiring pattern members of the intermediate insulating layer 21. Although not illustrated, the wiring hole 25i is electrically connected to another wiring layer of the wiring board 20 (for example, the fourth wiring layer which is a lowermost layer), and is electrically connected, in the wiring layer, to the external connection terminal 32f.

In addition, the external connection terminals 32a to 32f are bonded to the wiring board 20. Each of the external connection terminals 32a to 32f is electrically connected to a conductive wiring pattern member of at least one wiring layer included in the wiring board 20.

Although not illustrated, for example, the external connection terminal 32a is electrically connected to a conductive wiring pattern member formed in the first wiring layer, and the conductive wiring pattern member is electrically connected to the wiring holes 24a and 24b. Accordingly, the external connection terminal 32a functions as a gate control terminal for inputting a control signal to control electrodes of the semiconductor chips 33a and 33b. In addition, for example, the external connection terminal 32b is electrically connected to a conductive wiring pattern member formed in the first wiring layer, and the conductive wiring pattern member is electrically connected to the wiring holes 24c and 24d. Accordingly, the external connection terminal 32b functions as a gate control terminal for inputting a control signal to control electrodes of the semiconductor chips 33c and 33d.

In addition, the external connection terminal 32c is electrically connected to a conductive wiring pattern member formed in the fourth wiring layer, and the conductive wiring pattern member is electrically connected to the wiring holes 23a and 23b. Accordingly, the external connection terminal 32c functions as an auxiliary source terminal connected to output electrodes (source electrodes) of the semiconductor chips 33a and 33b. In addition, the external connection terminal 32d is electrically connected to a conductive wiring pattern member formed in the fourth wiring layer, and the conductive wiring pattern member is electrically connected to the wiring holes 23c and 23d. Accordingly, the external connection terminal 32d functions as an auxiliary source terminal connected to output electrodes (source electrodes) of the semiconductor chips 33c and 33d.

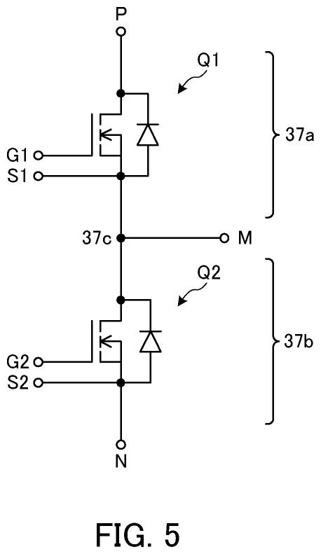

FIG. 5 illustrates an example of a circuit configuration of an inverter circuit. The semiconductor module 2 includes, for example, an inverter circuit as illustrated in FIG. 5. This inverter circuit includes transistors (MOS-FETs) Q1 and Q2. The transistor Q1 constitutes an upper arm portion 37a of a half-bridge circuit, and the transistor Q2 constitutes a lower arm portion 37b of the half-bridge circuit. The transistor Q1 corresponds to the semiconductor chips 33a and 33b, and the transistor Q2 corresponds to the semiconductor chips 33c and 33d.

Drain electrodes of the transistor Q1 are connected to a P terminal constituting a positive-side input terminal of the half-bridge circuit. The transistor Q1 corresponds to the semiconductor chips 33a and 33b, and the P terminal corresponds to the external connection terminals 31a and 31b. As described above, the input electrodes (the drain electrodes) on the lower surfaces of the semiconductor chips 33a are electrically connected to the external connection terminal 31a serving as the P terminal via the conductive circuit pattern member 13a. Further, the input electrodes (the drain electrodes) on the lower surfaces of the semiconductor chips 33b are electrically connected to the external connection terminal 31b serving as the P terminal via the conductive circuit pattern member 13b.

Source electrodes of the transistor Q2 are connected to an N terminal constituting a negative-side input terminal of the half-bridge circuit. The transistor Q2 corresponds to the semiconductor chips 33c and 33d, and the N terminal corresponds to the external connection terminal 31c. As described above, the output electrodes (the source electrodes) on the upper surfaces of the semiconductor chips 33c are electrically connected to the external connection terminal 31c serving as the N terminal via the wiring pins 34c, the conductive wiring pattern member 22c, the wiring members 36a to 36c, and the conductive circuit pattern member 13c. Further, the output electrodes (the source electrodes) on the upper surfaces of the semiconductor chips 33d are electrically connected to the external connection terminal 31c serving as the N terminal via the wiring pins 34d, the conductive wiring pattern member 22c, the wiring members 36a to 36c, and the conductive circuit pattern member 13c.

The source electrodes of the transistor Q1 and the drain electrodes of the transistor Q2 are connected at a connection point 37c, and this connection point 37c is connected to an M terminal constituting an output terminal of the half-bridge circuit. The M terminal corresponds to the external connection terminal 31d. As described above, the output electrodes (the source electrodes) on the upper surfaces of the semiconductor chips 33a are electrically connected to the input electrodes (the drain electrodes) on the lower surfaces of the semiconductor chips 33c and 33d and to the external connection terminal 31d serving as the M terminal via the wiring pins 34a, the conductive wiring pattern member 22a, the wiring members 36d and 36e, and the conductive circuit pattern member 13d. Further, the output electrodes (the source electrodes) on the upper surfaces of the semiconductor chips 33b are electrically connected to the input electrodes (the drain electrodes) on the lower surfaces of the semiconductor chips 33c and 33d and to the external connection terminal 31d serving as the M terminal via the wiring pins 34b, the conductive wiring pattern member 22b, the wiring members 36f and 36g, and the conductive circuit pattern member 13d.

Gate electrodes of the transistor Q1 are connected to a gate terminal G1 serving as an input terminal of a control signal for switching operation. The gate terminal G1 corresponds to the external connection terminal 32a. As described above, the control electrodes (the gate electrodes) on the upper surfaces of the semiconductor chips 33a are electrically connected to the external connection terminal 32a serving as the gate terminal G1 via the wiring pins 35a and a predetermined conductive wiring pattern member of the wiring board 20 (for example, a conductive wiring pattern member of a first wiring layer). Further, the control electrodes (the gate electrodes) on the upper surfaces of the semiconductor chips 33b are electrically connected to the external connection terminal 32a serving as the gate terminal G1 via the wiring pins 35b and a predetermined conductive wiring pattern member of the wiring board 20 (for example, a conductive wiring pattern member of the first wiring layer).

Gate electrodes of the transistor Q2 are connected to a gate terminal G2 serving as an input terminal of a control signal for switching operation. The gate terminal G2 corresponds to the external connection terminal 32b. As described above, the control electrodes (the gate electrodes) on the upper surfaces of the semiconductor chips 33c are electrically connected to the external connection terminal 32b serving as the gate terminal G2 via the wiring pins 35c and a predetermined conductive wiring pattern member of the wiring board 20 (for example, a conductive wiring pattern member of the first wiring layer). Further, the control electrodes (the gate electrodes) on the upper surfaces of the semiconductor chips 33d are electrically connected to the external connection terminal 32b serving as the gate terminal G2 via the wiring pins 35d and a predetermined conductive wiring pattern member of the wiring board 20 (for example, a conductive wiring pattern member of the first wiring layer).

The source electrodes of the transistor Q1 are also connected to an auxiliary source terminal S1. The auxiliary source terminal S1 corresponds to the external connection terminal 32c. Further, the source electrodes of the transistor Q2 are also connected to an auxiliary source terminal S2. The auxiliary source terminal S2 corresponds to the external connection terminal 32d.

In the semiconductor device 1 according to the present embodiment, eight sets of the transistors Q1 and Q2 are mounted. Accordingly, the semiconductor device 1 includes eight inverter circuits each including the transistors Q1 and Q2. These inverter circuits are connected in parallel. Although not illustrated, for example, three semiconductor devices 1 each including such parallel inverter circuits may be used in combination. In this case, one semiconductor device 1 generates a U-phase output voltage, another semiconductor device 1 generates a V-phase output voltage, and the remaining semiconductor device 1 generates a W-phase output voltage.

FIG. 6 is a perspective view illustrating shapes of wiring members. Since the wiring members 36a to 36i have the same size and the same shape, these wiring members are collectively referred to as “wiring members 36”.

Each wiring member 36 includes the lower spacer portion 361 and the upper connecting portion 362. The spacer portion 361 includes an upper end surface 361a bonded around the wiring holes 25a to 25i (the third wiring holes) on a lower surface (opposing surface) of the wiring board 20, and a lower end surface 361b bonded to upper surfaces of the conductive circuit pattern members 13c to 13e of the insulating circuit board 10. The spacer portion 361 maintains the predetermined interval D1 between the lower surface (opposing surface) of the wiring board 20 and the upper surfaces of the conductive circuit pattern members 13c to 13e of the insulating circuit board 10. The connecting portion 362 is formed within the upper end surface 361a of the spacer portion 361 and is inserted into the wiring holes 25a to 25i (the third wiring holes).

In the example illustrated in FIG. 6, the spacer portion 361 has a cylindrical shape with a height of D1, and the connecting portion 362 has a cylindrical shape thinner than the spacer portion 361.

Each wiring member 36 electrically connects a wiring hole formed in the wiring board 20 and a conductive circuit pattern member formed on the insulating circuit board 10, and maintains the interval D1 between the lower surface (opposing surface) of the wiring board 20 and the upper surfaces of the conductive circuit pattern members of the insulating circuit board 10. Each wiring member 36 may also be referred to as a “wiring pin with spacer” having both a wiring pin function and a spacer function.

When a thickness (for example, a diameter) of the connecting portion 362 is the same as thicknesses (for example, opening diameters) of the wiring pins 34a to 34d and 35a to 35d, current flows through the spacer portion 361, which is thicker than the connecting portion 362 and the wiring pins 34a to 34d and 35a to 35d, thereby making it possible to enhance heat dissipation of heat generated by the current.

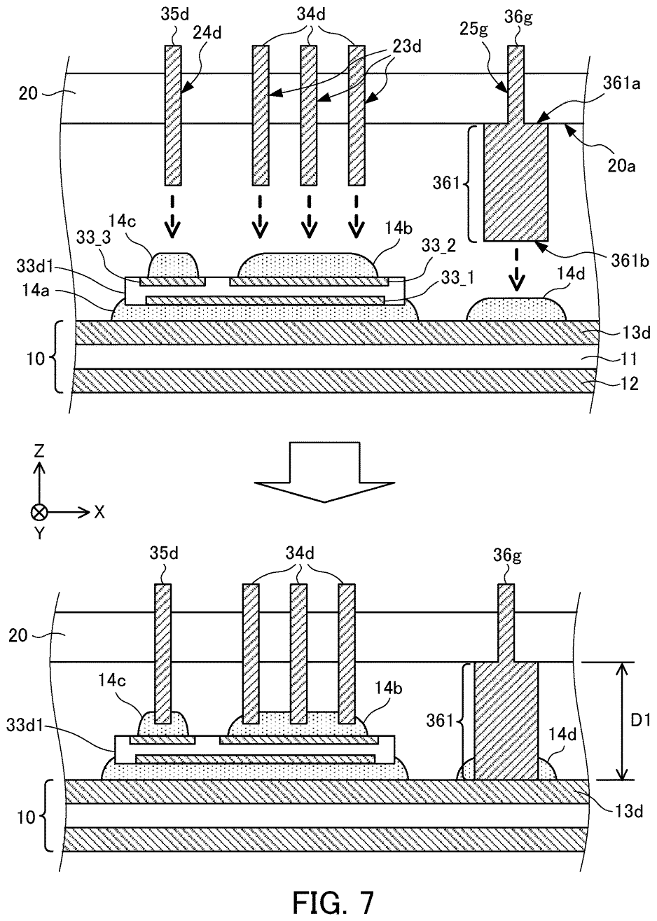

FIG. 7 is an enlarged cross-sectional view of attachment regions of wiring pins and wiring members. FIG. 7 is an enlarged cross-sectional view obtained by cutting a region A of FIG. 2 along line I1-I1 of FIG. 3, and illustrates a semiconductor chip 33d1, the conductive circuit pattern member 13d, the wiring pins 34d and 35d, and the wiring member 36g. An upper part of FIG. 7 illustrates a state before bonding of the wiring pins 34d and 35d to the semiconductor chip 33d1 and bonding of the wiring member 36g to the conductive circuit pattern member 13d, and a lower part of FIG. 7 illustrates a bonded state thereof.

As illustrated in the upper part of FIG. 7, the wiring pins 34d and 35d and the wiring member 36g are respectively inserted into the wiring holes 23d, 24d, and 25g of the wiring board 20. At this time, the upper end surface 361a of the spacer portion 361 of the wiring member 36g is bonded around the wiring hole 25g to the lower surface (an opposing surface 20a opposing the insulating circuit board 10) of the wiring board 20.

Further, the semiconductor chip 33d1 is bonded to the upper surface of the conductive circuit pattern member 13d via a bonding material 14a. Accordingly, an input electrode 33_1 on a lower surface of the semiconductor chip 33d1 is electrically connected to the conductive circuit pattern member 13d via the bonding material 14a. Bonding materials 14b and 14c are arranged on upper surfaces of an output electrode 33_2 and a control electrode 33_3 of the semiconductor chip 33d1, respectively, and a bonding material 14d is arranged at a position on the upper surface of the conductive circuit pattern member 13d opposing the wiring member 36g.

From this state, the wiring board 20 is moved toward the insulating circuit board 10 until the lower end surface 361b of the spacer portion 361 of the wiring member 36g comes into contact with the conductive circuit pattern member 13d. As illustrated in the lower part of FIG. 7, when the lower end surface 361b of the spacer portion 361 comes into contact with the conductive circuit pattern member 13d, lower ends of the wiring pins 34d and 35d respectively come into contact with the bonding materials 14b and 14c. However, lower end surfaces of the wiring pins 34d and 35d do not contact the upper surface of the semiconductor chip 33d1, and an interval is maintained therebetween.

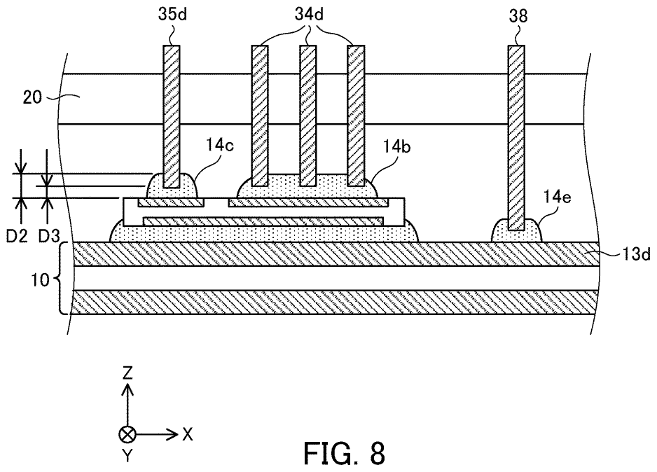

Here, a comparative example in which a wiring pin is used instead of the wiring member 36g in FIG. 7 will be described. FIG. 8 illustrates a comparative example relating to bonding of a wiring pin.

In FIG. 8, a wiring pin 38 is inserted into the wiring hole 25g of the wiring board 20 instead of the wiring member 36g. Further, similarly to FIG. 7, the bonding materials 14b and 14c are respectively disposed on surfaces of the output electrode 33_2 and the control electrode 33_3 on the upper surface of the semiconductor chip 33d1. Furthermore, a bonding material 14e is disposed at a position on an upper surface of the conductive circuit pattern member 13d facing the wiring pin 38. From this state, the wiring board 20 is moved toward the insulating circuit board 10.

In this case, a lower end of the wiring pin 38 comes into contact with the bonding material 14e, while not coming into contact with the upper surface of the conductive circuit pattern member 13d. Further, similarly to FIG. 7, lower ends of the wiring pins 34d and 35d respectively come into contact with the bonding materials 14b and 14c, while lower end surfaces of the wiring pins 34d and 35d do not come into contact with the upper surface of the semiconductor chip 33d1. For example, while a thickness D2 of the bonding materials 14b and 14c disposed on the semiconductor chip 33d1 is set to 50 to 400 μm, a designed interval D3 between the lower end surfaces of the wiring pins 34d and 35d and the upper surface of the semiconductor chip 33d1 is set to 10 to 300 μm.

However, when the wiring board 20 is moved toward the insulating circuit board 10, a load (stress) may occur in a downward direction (−Z direction) from an upper side of the wiring board 20, for example due to pressurization by a jig. Due to this load, the lower end surfaces of the wiring pins 34d and 35d may come into contact with the upper surface of the semiconductor chip 33d1, and in some cases, the semiconductor chip 33d1 may be damaged due to occurrence of cracks or the like.

Further, also in a process from bonding of the lower ends of the wiring pins 34d and 35d to the upper surface of the semiconductor chip 33d1 via the bonding materials 14b and 14c until sealing by the sealing member 5 is performed, a load may occur in the downward direction (−Z direction) from the upper side of the wiring board 20. Also in this case, the lower end surfaces of the wiring pins 34d and 35d may come into contact with the upper surface of the semiconductor chip 33d1, and the semiconductor chip 33d1 may be damaged.

To cope with such problems, in a case in which the wiring member 36g is used as illustrated in FIG. 7, a spacing between the lower surface (the opposing surface 20a) of the wiring board 20 and the upper surface of the conductive circuit pattern member 13d of the insulating circuit board 10 is maintained at the interval D1 by the spacer portion 361 of the wiring member 36g. Accordingly, even when a load occurs in the downward direction (−Z direction) from the upper side of the wiring board 20, a possibility that the lower end surfaces of the wiring pins 34d and 35d come into contact with the upper surface of the semiconductor chip 33d1 is reduced. As a result, a possibility that the semiconductor chip 33d1 is damaged due to occurrence of the load is reduced.

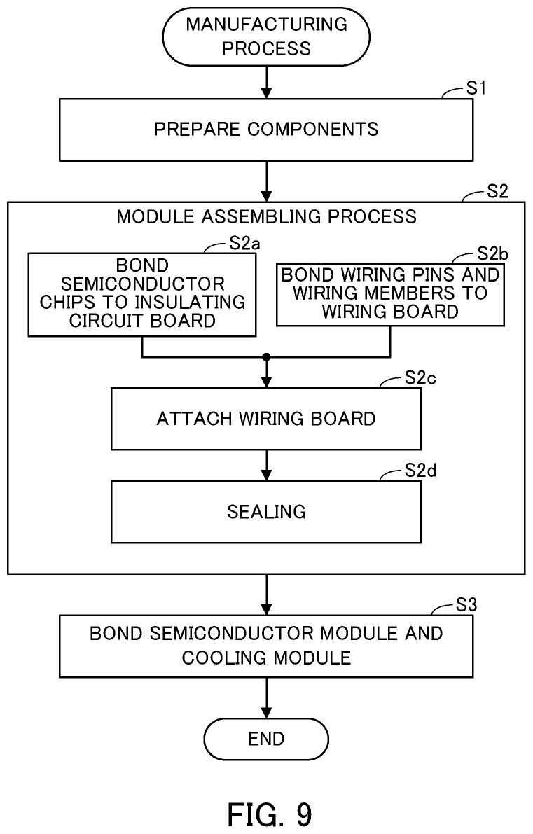

FIG. 9 is a flowchart illustrating a manufacturing process of the semiconductor device.
[Step S1] A preparation step of preparing components of the semiconductor device 1 is performed. Examples of the components prepared here include the insulating circuit board 10, the wiring board 20, the semiconductor chips 33a to 33d, the wiring pins 34a to 34d and 35a to 35d, the wiring members 36a to 36i, and the sealing member 5 that configure the semiconductor module 2, and the cooler 3. Components not listed here may also be prepared, provided that the components are used for manufacturing the semiconductor device 1. Manufacturing apparatuses used for manufacturing the semiconductor device 1 may also be prepared. Examples of the manufacturing apparatuses include a coating apparatus that applies solder, and a molding apparatus for sealing with the sealing member.
[Step S2] A module assembling process of assembling the semiconductor module 2 is performed. The module assembling process includes, for example, the following steps S2a to S2d.
(Step S2a) The semiconductor chips 33a to 33d are bonded, via the bonding material 14a, to upper surfaces of the conductive circuit pattern members of the insulating circuit board 10.
(Step S2b) In parallel with step S2a, the wiring pins 34a to 34d and 35a to 35d are respectively inserted into the wiring holes 23a to 23d and 24a to 24d of the wiring board 20, and are bonded. Further, the connecting portions 362 of the wiring members 36a to 36i are respectively inserted into the wiring holes 25a to 25i of the wiring board 20, and are bonded. At this time, the upper end surfaces 361a of the spacer portions 361 of the wiring members 36a to 36i are bonded to the lower surface (the opposing surface 20a) of the wiring board 20.
Steps S2a and S2b are performed before step S2c. For example, one of steps S2a and S2b may be performed first, and the other step may be performed later.
(Step S2 c) The wiring board 20 to which the wiring pins 34a to 34d and 35a to 35d and the wiring members 36a to 36i are bonded is attached to the insulating circuit board 10 to which the semiconductor chips 33a to 33d are bonded.

In step S2c, the bonding material 14b is disposed on an upper surface of the output electrode 33_2 of each of the semiconductor chips 33a to 33d, and the bonding material 14c is disposed on an upper surface of the control electrode 33_3 of each of the semiconductor chips 33a to 33d. Further, bonding materials 14d are disposed at positions on upper surfaces of the conductive circuit pattern members of the insulating circuit board 10 respectively facing the wiring members 36a to 36i.

From this state, the wiring board 20 is moved toward the insulating circuit board 10 until the lower end surfaces 361b of the spacer portions 361 of the wiring members 36a to 36i come into contact with the upper surfaces of the conductive circuit pattern members of the insulating circuit board 10. In a state in which the upper surfaces of the conductive circuit pattern members are in contact with the lower end surfaces 361b of the spacer portions 361, a spacing between the lower surface (the opposing surface 20a) of the wiring board 20 and the upper surfaces of the conductive circuit pattern members of the insulating circuit board 10 is maintained at the interval D1 by the spacer portions 361 of the wiring members 36a to 36i. Accordingly, the lower ends of the wiring pins 34d and 35d come into contact with the bonding materials 14b and 14c, respectively, in a state spaced apart from the upper surfaces of the semiconductor chips 33a to 33d. Therefore, a possibility that the lower ends of the wiring pins 34d and 35d collide with the semiconductor chips 33a to 33d and the semiconductor chips 33a to 33d are damaged is reduced.

As described above, in the state in which the upper surfaces of the conductive circuit pattern members are in contact with the lower end surfaces 361b of the spacer portions 361 of the wiring members 36a to 36i, reflow is performed. The bonding materials 14b to 14d are melted by heating, and thereafter cooled so that the bonding materials 14b to 14d are hardened. As a result, the wiring pins 34d and 35d are bonded, via the bonding materials 14b and 14c, to the upper surfaces of the semiconductor chips 33a to 33d, respectively. Further, in the state in which the lower end surfaces 361b of the spacer portions 361 of the wiring members 36a to 36i are in contact with the upper surfaces of the conductive circuit pattern members of the insulating circuit board 10, the wiring members 36a to 36i and the upper surfaces of the conductive circuit pattern members of the insulating circuit board 10 are bonded by the bonding materials 14d.

Step S2b may be included in step S2a. Further, reflow for bonding the semiconductor chips in step S2a and reflow for bonding the wiring pins 34a to 34d and 35a to 35d and the wiring members 36a to 36i in step S2c may be performed in the same process. In this case, the bonding materials 14a are disposed on the upper surfaces of the conductive circuit pattern members of the insulating circuit board 10, and the semiconductor chips 33a to 33d are disposed on the bonding materials 14a. Further, the bonding materials 14b and 14c are respectively disposed on the upper surfaces of the output electrodes 33_2 and the control electrodes 33_3 of the semiconductor chips 33a to 33d. Further, the bonding materials 14d are disposed at positions on the upper surfaces of the conductive circuit pattern members of the insulating circuit board 10 respectively facing the wiring members 36a to 36i. From this state, the wiring board 20 is moved toward the insulating circuit board 10 until the lower end surfaces 361b of the spacer portions 361 of the wiring members 36a to 36i come into contact with the upper surfaces of the conductive circuit pattern members of the insulating circuit board 10, and reflow is performed.
(Step S2d) The insulating circuit board 10 and the wiring board 20 are sealed by the sealing member 5. In step S2d, the insulating circuit board 10 to which the wiring board 20 is attached is set in a cavity of a predetermined molding apparatus. In the molding apparatus, molten sealing material in the pot is pressurized by a plunger, transferred from the pot to a runner, and injected into the cavity. Thereafter, the sealing raw material is hardened, and the insulating circuit board 10 and the wiring board 20 are sealed by the sealing member 5. A region between the insulating circuit board 10 and the wiring board 20 is sealed by the sealing member 5, and at least side-surface-side regions (±X-direction-side regions and ±Y-direction-side regions) of the insulating circuit board 10 and the wiring board 20 and an upper-surface-side region of the wiring board 20 are also sealed by the sealing member 5.
[Step S3] The cooler 3 is bonded, via the bonding material 4, to a lower surface of the semiconductor module 2. In step S3, for example, the cooler 3 is fixed to a predetermined fixing base, and the semiconductor module 2 is set with respect to the bonding material 4 (for example, a thermally conductive adhesive) applied to an upper surface of the cooler 3. Then, by heating the bonding material 4, the lower surface of the semiconductor module 2 and the upper surface of the cooler 3 are bonded.

Next, a position at which the wiring members 36a to 36i are disposed with respect to the insulating circuit board 10 will be described.

In the present embodiment, a wiring member is disposed, in plan view, in a region between a first semiconductor chip and a second semiconductor chip on the insulating circuit board 10.

For example, a semiconductor chip 33a1 (the first semiconductor chip) includes, on an upper surface, the output electrode 33_2 and the control electrode 33_3 (the first electrode), and a semiconductor chip 33b1 (the second semiconductor chip) includes, on an upper surface, the output electrode 33_2 and the control electrode 33_3 (the second electrode).

In the wiring board 20, the wiring holes 23a and 24a (the first wiring hole), the wiring holes 23b and 24b (the second wiring hole), and the wiring hole 25a (the third wiring hole) are formed. The wiring holes 23a and 24a face the output electrode 33_2 and the control electrode 33_3 of the semiconductor chip 33a1, respectively, and the wiring holes 23b and 24b face the output electrode 33_2 and the control electrode 33_3 of the semiconductor chip 33b1, respectively. The wiring pins 34a and 35a (the first wiring pin) are respectively inserted into the wiring holes 23a and 24a. A lower end of the wiring pin 34a is electrically connected, via the bonding material 14b, to the output electrode 33_2 of the semiconductor chip 33a1. A lower end of the wiring pin 35a is electrically connected, via the bonding material 14c, to the control electrode 33_3. The wiring pins 34b and 35b (the second wiring pin) are respectively inserted into the wiring holes 23b and 24b. A lower end of the wiring pin 34b is electrically connected, via the bonding material 14b, to the output electrode 33_2 of the semiconductor chip 33b1. A lower end of the wiring pin 35b is electrically connected, via the bonding material 14c, to the control electrode 33_3. The connecting portion 362 of the wiring member 36a is inserted into the wiring hole 25a. The upper end surface 361a of the spacer portion 361 of the wiring member 36a is bonded to the lower surface (the opposing surface 20a) of the wiring board 20, and the lower end surface 361b of the spacer portion 361 of the wiring member 36a is bonded to the conductive circuit pattern member 13c of the insulating circuit board 10.

The lower end surface 361b of the spacer portion 361 of the wiring member 36a is bonded to the conductive circuit pattern member 13c in a region between the semiconductor chip 33a1 and the semiconductor chip 33b1 on the insulating circuit board 10.

Further, for example, a semiconductor chip 33b2 (the first semiconductor chip) includes, on an upper surface, the output electrode 33_2 and the control electrode 33_3 (the first electrode), and a semiconductor chip 33d1 (the second semiconductor chip) includes, on an upper surface, the output electrode 33_2 and the control electrode 33_3 (the second electrode).

In the wiring board 20, the wiring holes 23b and 24b (the first wiring hole), the wiring holes 23d and 24d (the second wiring hole), and the wiring hole 25g (the third wiring hole) are formed. The wiring holes 23b and 24b face the output electrode 33_2 and the control electrode 33_3 of the semiconductor chip 33b2, respectively, and the wiring holes 23d and 24d face the output electrode 33_2 and the control electrode 33_3 of the semiconductor chip 33d1, respectively. The wiring pins 34b and 35b (the first wiring pin) are respectively inserted into the wiring holes 23b and 24b. A lower end of the wiring pin 34b is electrically connected, via the bonding material 14a, to the output electrode 33_2 of the semiconductor chip 33b2. A lower end of the wiring pin 35b is electrically connected, via the bonding material 14b, to the control electrode 33_3. The wiring pins 34d and 35d (the second wiring pin) are respectively inserted into the wiring holes 23d and 24d. A lower end of the wiring pin 34d is electrically connected, via the bonding material 14b, to the output electrode 33_2 of the semiconductor chip 33d1. A lower end of the wiring pin 35d is electrically connected, via the bonding material 14c, to the control electrode 33_3. The connecting portion 362 of the wiring member 36g is inserted into the wiring hole 25g. The upper end surface 361a of the spacer portion 361 of the wiring member 36g is bonded to the lower surface (the opposing surface 20a) of the wiring board 20, and the lower end surface 361b of the spacer portion 361 of the wiring member 36g is bonded to the conductive circuit pattern member 13d of the insulating circuit board 10.

The lower end surface 361b of the spacer portion 361 of the wiring member 36g is bonded to the conductive circuit pattern member 13d in a region between the semiconductor chip 33b2 and the semiconductor chip 33d1 on the insulating circuit board 10.

As described above, a wiring member is disposed, in plan view, in a region between the first semiconductor chip and the second semiconductor chip on the insulating circuit board 10. As a result, when a load is applied in a downward direction (−Z direction) from an upper side of the wiring board 20 in the region between the first semiconductor chip and the second semiconductor chip, a spacing between an upper surface of the insulating circuit board 10 and a lower surface of the wiring board 20 in the region is maintained at a spacing equal to a height of the spacer portion of the wiring member. Therefore, a possibility that lower ends of the first wiring pin and the second wiring pin collide with upper surfaces of the first semiconductor chip and the second semiconductor chip, thereby damaging the first semiconductor chip and the second semiconductor chip, is reduced.

Further, in the present embodiment, the semiconductor chip 33a1 (the first semiconductor chip) and the semiconductor chip 33b1 (the second semiconductor chip) are disposed to face each other across the first center line L1 of the insulating circuit board 10 in plan view, and a plurality of wiring members (the wiring members 36a to 36c) is arranged on the conductive circuit pattern member 13c along the first center line L1. For example, when a plurality of wiring members is arranged, at positions located in a region where the semiconductor chips 33a1 and 33b1 face each other, along sides extending in the ±X direction of the insulating circuit board, downward strength of the wiring board 20 in the region between the semiconductor chips 33a1 and 33b1 is weak when a load is applied in the downward direction (−Z direction) from the upper side of the wiring board 20, and the region may bend downward. In that case, a possibility arises that lower ends of the wiring pins 34a and 35a collide with the upper surface of the semiconductor chip 33a1 and the semiconductor chip 33a1 is damaged, and a possibility arises that lower ends of the wiring pins 34b and 35b collide with the upper surface of the semiconductor chip 33b1 and the semiconductor chip 33b1 is damaged. On the other hand, with the above configuration of the present embodiment in which the plurality of wiring members is arranged along the first center line L1, a possibility that the semiconductor chips 33a1 and 33b1 are damaged is reduced.

Further, in the present embodiment, a plurality of wiring members (the wiring members 36d to 36g) is arranged on the conductive circuit pattern member 13d along the second center line L2 that is orthogonal to the first center line L1 on the insulating circuit board 10 in plan view. As a result, when a load is applied in the downward direction (−Z direction) from the upper side of the wiring board 20 in a region between semiconductor chips that are disposed to face each other across the second center line L2 (for example, the semiconductor chips 33b2 and 33d1), a possibility that those semiconductor chips are damaged is reduced. The second center line L2 is not limited to a line strictly centered in the ±X direction on the insulating circuit board 10, and may be a line near a center in the ±X direction.

Further, in the present embodiment, on the upper surface of the insulating circuit board 10, the conductive circuit pattern member 13c (the first conductive circuit pattern member) extending along the first center line L1 and the conductive circuit pattern members 13a and 13b (the second conductive circuit pattern member and the third conductive circuit pattern member) disposed to face each other across the conductive circuit pattern member 13c are formed. The semiconductor chip 33a1 (the first semiconductor chip) is disposed on the conductive circuit pattern member 13a, and the semiconductor chip 33b1 (the second semiconductor chip) is disposed on the conductive circuit pattern member 13b. The plurality of wiring members (the wiring members 36a to 36c) is disposed on the conductive circuit pattern member 13c along the first center line L1. As a result, when a load is applied in the downward direction (−Z direction) from the upper side of the wiring board 20 in a region between the semiconductor chips 33a1 and 33b1, a possibility that the semiconductor chips 33a1 and 33b1 are damaged is reduced.

Further, in the present embodiment, on the upper surface of the insulating circuit board 10, the conductive circuit pattern member 13d (the fourth conductive circuit pattern member) on which a plurality of semiconductor chips 33c and 33d (the third semiconductor chips) is disposed is formed. On the wiring board 20, the conductive wiring pattern member 22c is formed. A current path is formed between the output electrodes 33_2 on the upper surfaces of the semiconductor chips 33c and 33d and the conductive circuit pattern member 13c, via the conductive wiring pattern member 22c and the wiring members 36a to 36c. Further, the connecting portions 362 of the wiring members 36a to 36c may have a columnar shape, and the spacer portions 361 of the wiring members 36a to 36c may have a columnar shape thicker than the connecting portions 362.

A large source current flows in a current path between the output electrodes (source electrodes) 33_2 on the upper surfaces of the semiconductor chips 33c and 33d and the conductive circuit pattern member 13c (and the external connection terminal 31c), and large Joule heat is likely to be generated in the current path. On the other hand, when the conductive wiring pattern member 22c of the wiring board 20 and the conductive circuit pattern member 13c of the insulating circuit board 10 are electrically connected by a plurality of wiring members (the wiring members 36a to 36c) each including, for example, the spacer portion 361 thicker than a thickness of a wiring pin, a heat dissipation effect when the source current flows is enhanced.

Further, in the present embodiment, on the upper surface of the insulating circuit board 10, the conductive circuit pattern member 13b (the fifth conductive circuit pattern member) on which the semiconductor chip 33b2 (the first semiconductor chip) is disposed and the conductive circuit pattern member 13d (the sixth conductive circuit pattern member) on which the semiconductor chip 33d1 (the second semiconductor chip) is disposed are formed. A plurality of wiring members (the wiring members 36d to 36g) is arranged in an edge region of the conductive circuit pattern member 13d along the boundary line 13d2 facing the conductive circuit pattern member 13b. As a result, when a load is applied in the downward direction (−Z direction) from the upper side of the wiring board 20 in a region between the semiconductor chips 33b2 and 33d1, a possibility that the semiconductor chips 33b2 and 33d1 are damaged is reduced.

### Modification Examples of Semiconductor Module

Next, modification examples in which part of the configuration of the semiconductor module 2 is modified will be described.

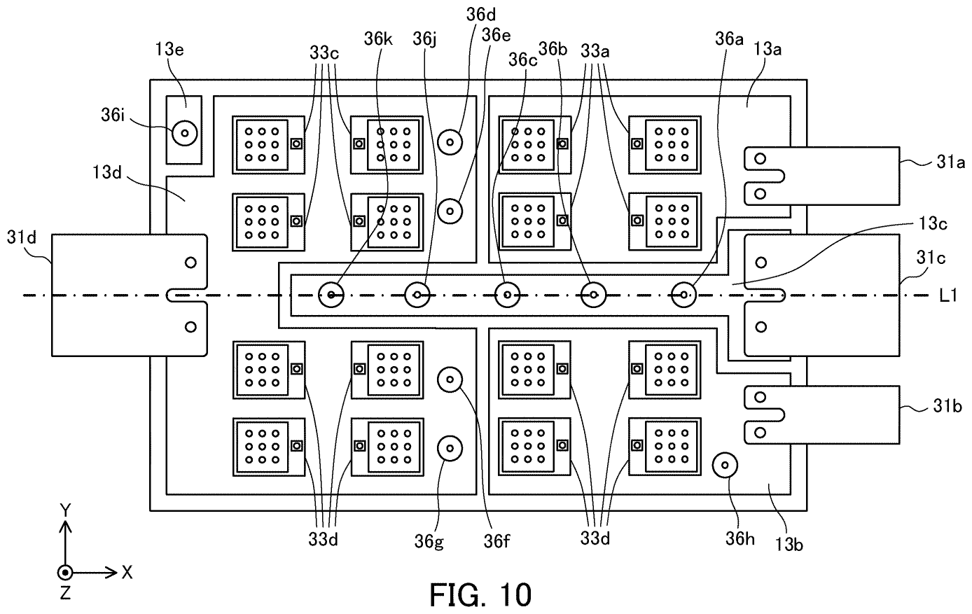

FIG. 10 illustrates a modification example in which part of a conductive circuit pattern member of the insulating circuit board is modified. As in FIG. 3, FIG. 10 illustrates, for ease of understanding, a state in which wiring pins and wiring members are respectively bonded to semiconductor chips and conductive circuit pattern members on the insulating circuit board 10.

In the insulating circuit board 10 illustrated in FIG. 10, a region of the conductive circuit pattern member 13c on the −X-direction side further extends toward the −X-direction side. By extending the region of the conductive circuit pattern member 13c in this manner, a larger number of wiring members is bondable to the conductive circuit pattern member 13c. In the example of FIG. 10, wiring members 36j and 36k are bonded to the upper surface of the conductive circuit pattern member 13c in addition to the wiring members 36a to 36c. The wiring members 36a to 36c, 36j, and 36k are arranged along the first center line L1. Further, the connecting portions 362 of the wiring members 36a to 36c, 36j, and 36k are inserted into wiring holes formed in the wiring board 20 and electrically connected to the conductive wiring pattern member 22c of the wiring board 20. Accordingly, the conductive circuit pattern member 13c is electrically connected to the conductive wiring pattern member 22c via the wiring members 36a to 36c, 36j, and 36k.

As described above, a large source current flows in a current path between the output electrodes (source electrodes) 33_2 on the upper surfaces of the semiconductor chips 33c and 33d and the conductive circuit pattern member 13c, and further to the external connection terminal 31c, and large Joule heat is likely to be generated in the current path. With the configuration of FIG. 10, the conductive circuit pattern member 13c of the insulating circuit board 10 and the conductive wiring pattern member 22c of the wiring board 20 are connected via a larger number of wiring members 36a to 36c, 36j, and 36k, thereby further enhancing a heat dissipation effect when the source current flows.

Next, modification examples of shapes of the wiring members will be described.

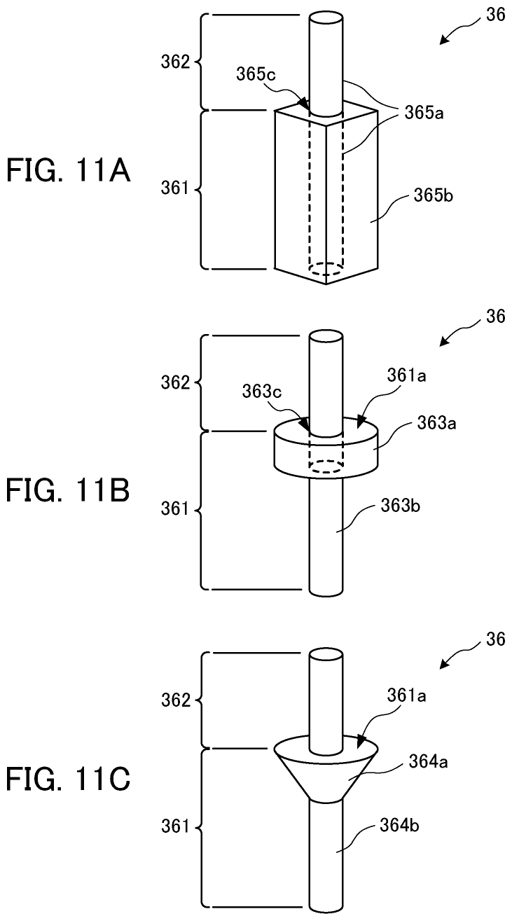

FIGS. 11A to 11C illustrate modification examples of shapes of the wiring members.

In the wiring member 36 illustrated in FIG. 11A, the connecting portion 362 has a cylindrical shape, whereas the spacer portion 361 has a prismatic shape. In this manner, when the spacer portion 361 is thicker than the connecting portion 362, cross-sectional shapes of the spacer portion 361 and the connecting portion 362, each having a columnar shape, are selectable as desired.

In the wiring member 36 illustrated in FIG. 11B, the spacer portion 361 includes an upper member 363a and a lower member 363b. Each of the upper member 363a and the lower member 363b has a columnar shape (a cylindrical shape in this example), and the upper member 363a is thicker than the lower member 363b. The upper end surface 361a of the upper member 363a is bonded around the wiring holes 25a to 25i on the lower surface (the opposing surface 20a) of the wiring board 20. The upper member 363a may be a flat-plate-shaped member forming a circle or a polygon in plan view. In this case, the upper end surface 361a of the flat-plate-shaped member is bonded around the wiring holes 25a to 25i on the lower surface (the opposing surface 20a) of the wiring board 20.

In the wiring member 36 illustrated in FIG. 11C as well, the spacer portion 361 includes an upper member 364a and a lower member 364b. The lower member 364b has a columnar shape (a cylindrical shape in this example). The lower member 364b may have a thickness equal to a thickness of the connecting portion 362. On the other hand, the upper member 364a has a tapered shape whose top is cut off and which is inverted upside down. That is, a thickness of the upper member 364a gradually decreases from an upper side toward a lower side. The upper end surface 361a of the upper member 364a is bonded around the wiring holes 25a to 25i on the lower surface (the opposing surface 20a) of the wiring board 20.

The wiring member 36 is manufacturable, for example, by cutting a metal material. Alternatively, the wiring member 36 is also manufacturable by combining a plurality of members. For example, the wiring member 36 illustrated in FIG. 11A includes a cylindrical member 365a having a height from an upper end to a lower end of the wiring member 36, and a prismatic member 365b having a height equal to a height of the spacer portion 361. A cylindrical through hole 365c extending in a vertical direction (±Z direction) is formed at a center portion of the prismatic member 365b. The wiring member 36 is manufactured by inserting the cylindrical member 365a into the through hole 365c.

Further, in the wiring member 36 illustrated in FIG. 11B, for example, the connecting portion 362 and the lower member 363b may be integrally formed as a cylindrical member having a height from an upper end to a lower end of the wiring member 36, and a through hole 363c may be formed at a center portion of the upper member 363a. Then, the cylindrical member is inserted into the through hole 363c, and the upper member 363a and the cylindrical member are joined by welding, thereby manufacturing the wiring member 36.

According to the disclosed technique, damage to semiconductor chips due to a load is prevented in a manufacturing process.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
an insulating circuit board including a conductive circuit pattern member, an upper surface of the conductive circuit pattern member being that of the insulating circuit board;
a first semiconductor chip and a second semiconductor chip formed on the insulating circuit board, and having a first electrode and a second electrode on upper surfaces thereof, respectively;
a wiring board having a lower surface facing the upper surface of the insulating circuit board, the wiring board having a first wiring hole, a second wiring hole, and a third wiring hole formed therein, the first wiring hole and the second wiring hole respectively facing the first electrode and the second electrode;
a first wiring pin and a second wiring pin respectively inserted into the first wiring hole and the second wiring hole, lower ends of the first wiring pin and the second wiring pin being electrically connected to the first electrode and the second electrode, respectively, via a bonding material; and
a conductive wiring member including:
a spacer portion, including:
an upper end surface bonded to the lower surface of the wiring board around the third wiring hole, and
a lower end surface bonded to the upper surface of the conductive circuit pattern member,
the spacer portion maintaining a predetermined interval between the lower surface of the wiring board and the upper surface of the conductive circuit pattern member; and
a connecting portion protruding upward from the upper end surface of the spacer portion and inserted into the third wiring hole,
wherein the lower end surface of the conductive wiring member is bonded to the conductive circuit pattern member in a region on the insulating circuit board between the first semiconductor chip and the second semiconductor chip.

2. The semiconductor device according to claim 1, wherein:
the insulating circuit board has a rectangular shape in a plan view of the semiconductor device,
the first semiconductor chip and the second semiconductor chip face each other across a first center line of the insulating circuit board in the plan view, and
the conductive wiring member is provided in a first plurality on the conductive circuit pattern member along the first center line.

3. The semiconductor device according to claim 2, wherein:
the conductive wiring member is further provided in a second plurality on the conductive circuit pattern member along a second center line of the insulating circuit board that is orthogonal to the first center line in the plan view.

4. The semiconductor device according to claim 2, wherein:
the conductive circuit pattern member includes
a first conductive circuit pattern member extending along the first center line, and
a second conductive circuit pattern member and a third conductive circuit pattern member, facing each other across the first conductive circuit pattern member,
the first semiconductor chip is on the second conductive circuit pattern member,
the second semiconductor chip is on the third conductive circuit pattern member, and
the first plurality of conductive wiring members is on the first conductive circuit pattern member along the first center line.

5. The semiconductor device according to claim 4, wherein:
the conductive circuit pattern member further includes a fourth conductive circuit pattern member having a plurality of third semiconductor chips on an upper surface thereof,
the wiring board includes a conductive wiring pattern member, and
a current path is formed between the plurality of third semiconductor chips and the first conductive circuit pattern member, and via the conductive wiring pattern member and the first plurality of conductive wiring members on the first conductive circuit pattern member.

6. The semiconductor device according to claim 5, wherein for each of the first plurality of conductive wiring members,
the connecting portion thereof has a first columnar shape, and
the spacer portion thereof has a second columnar shape having a larger diameter than a diameter of the connecting portion.

7. The semiconductor device according to claim 1, wherein:
the insulating circuit board has a rectangular shape in a plan view of the semiconductor device,
the conductive circuit pattern member includes
a fifth conductive circuit pattern member having the first semiconductor chip on an upper surface thereof, and
a sixth conductive circuit pattern member having the second semiconductor chip on an upper surface thereof, the sixth conductive circuit pattern member having a boundary line facing the fifth conductive circuit pattern member, and
the conductive wiring member is provided in a plurality in an edge region of the sixth conductive circuit pattern member along the boundary line thereof.
